(19) United States
(12) Patent Application Publication
(10) Pub. No.: US 2025/0258218 A1
(43) Pub. Date: Aug. 14, 2025

(54) ELECTRICAL CONNECTION APPARATUS

(71) Applicant: Kabushiki Kaisha Nihon Micronics, Tokyo (JP)

(72) Inventors: Souichi KANOSUE, Oita (JP); Masataka KIMOTO, Oita (JP); Toshihisa KADOWAKI, Oita (JP); Shin SAKIYAMA, Oita (JP)

(21) Appl. No.: 19/052,235

(22) Filed: Feb. 12, 2025

(30) Foreign Application Priority Data
Feb. 14, 2024 (JP) 2024-020424

(51) Int. Cl. G01R 31/28

(52) U.S. Cl. CPC G01R 31/2889

(57) ABSTRACT

An electrical connection apparatus includes a probe, a wiring board including a first electrode electrically connected to the probe, internal wiring, and a second electrode electrically connected to the first electrode via the internal wiring, and a wiring sheet with flexibility including a first connection portion arranged on a first sheet surface, a second connection portion arranged on a second sheet surface, and an internal circuit electrically connected to at least any one of the first connection portion and the second connection portion. A claw portion with conductivity projecting obliquely relative to a surface perpendicular to a thickness direction of the wiring sheet is arranged on at least any one of the first connection portion and the second connection portion. The internal wiring of the wiring board and the internal circuit of the wiring sheet are electrically connected via the claw portion.

### CROSS-REFERENCE TO RELATED APPLICATIONS

The present application is based on, and claims priority from Japanese Patent Application No. 2024-020424, filed on Feb. 14, 2024, the entire contents of which are incorporated herein by reference.

### TECHNICAL FIELD

The present disclosure relates to an electrical connection apparatus used for inspecting electrical characteristics of an object to be inspected.

### BACKGROUND ART

To measure electrical characteristics of an object to be inspected such as an integrated circuit, an electrical connection apparatus having a terminal for inspection in contact with the object to be inspected is used. In the measurement using the electrical connection apparatus, the object to be inspected is electrically connected to an inspection device such as a tester via the terminal for inspection. In order to measure various characteristics of the object to be inspected, the electrical connection apparatus is configured by superimposing a plurality of circuit boards such as a printed board and a space transformer.

### CITATION LIST

### Patent Literature

[Patent Literature 1] JP 2019-178901 A

### SUMMARY

If a plurality of circuit boards constituting an electrical connection apparatus have different degrees of flatness, a gap is formed between the circuit boards, and the stability of electrical connection between the circuit boards deteriorates. An object of the present disclosure is to provide an electrical connection apparatus in which electrical connection between circuit boards is stabilized.

An electrical connection apparatus according to one aspect of the present disclosure includes: a terminal for inspection; a wiring board including a first electrode electrically connected to the terminal for inspection, internal wiring, and a second electrode; and a wiring sheet with flexibility including a first connection portion arranged on a first sheet surface, a second connection portion arranged on a second sheet surface, and an internal circuit electrically connected to at least any one of the first connection portion and the second connection portion. A claw portion with conductivity projecting obliquely relative to a surface perpendicular to a thickness direction of the wiring sheet is arranged on at least any one of the first connection portion and the second connection portion. The internal wiring of the wiring board and the internal circuit of the wiring sheet are electrically connected via the claw portion.

### BRIEF DESCRIPTION OF THE DRAWINGS

FIG. 1 is a schematic view showing a configuration of an electrical connection apparatus according to a first embodiment.

FIG. 2A is a schematic plan view showing the configuration of the electrical connection apparatus according to the first embodiment.

FIG. 2B is a schematic cross-sectional view showing the configuration of the electrical connection apparatus according to the first embodiment.

FIG. 3 is a schematic cross-sectional view showing a configuration example of a wiring sheet in the electrical connection apparatus according to the first embodiment.

FIG. 4 is a schematic view showing configuration examples of claw portions of the wiring sheet in the electrical connection apparatus according to the first embodiment.

FIG. 5 is a schematic view showing arrangement examples of the claw portions of the wiring sheet in the electrical connection apparatus according to the first embodiment.

FIG. 6 is a schematic view showing examples of projecting directions of the claw portions of the wiring sheet in the electrical connection apparatus according to the first embodiment.

FIG. 7 is a schematic view showing another example of configurations of claw portions of the wiring sheet in the electrical connection apparatus according to the first embodiment.

FIG. 8 is a schematic view showing still another example of configurations of claw portions of the wiring sheet in the electrical connection apparatus according to the first embodiment.

FIG. 9 is a schematic view showing an example of an internal circuit of the wiring sheet in the electrical connection apparatus according to the embodiment.

FIG. 10 is a schematic view showing another example of the internal circuit of the wiring sheet in the electrical connection apparatus according to the embodiment.

FIG. 11 is a schematic view showing another example of the internal circuit of the wiring sheet in the electrical connection apparatus according to the embodiment.

FIG. 12 is a schematic view showing an example of a loopback circuit using the wiring sheet shown in FIG. 11.

FIG. 13 is a schematic view showing another example of the internal circuit of the wiring sheet in the electrical connection apparatus according to the embodiment.

FIG. 14 is a schematic view showing another example of the internal circuit of the wiring sheet in the electrical connection apparatus according to the embodiment.

FIG. 15 is a schematic view showing a configuration of an electrical connection apparatus according to a second embodiment.

FIG. 16 is a schematic view showing a configuration of an electrical connection apparatus according to a third embodiment.

### DETAILED DESCRIPTION

Embodiments will be described with reference to the drawings. In the description of the drawings below, the same or similar parts are denoted with the same or similar reference numerals. However, it should be noted that the drawings are schematically shown and the ratios of the thickness of each portion and the like are different from those in reality. Further, it is needless to say that the drawings include portions where the relationships and ratios of dimensions are different between drawings. The following embodiments exemplify an apparatus and a method for embodying the technical concept of the present invention, and the embodiments do not specify the material, shape, structure, arrangement, and the like of components to the following.

### First Embodiment

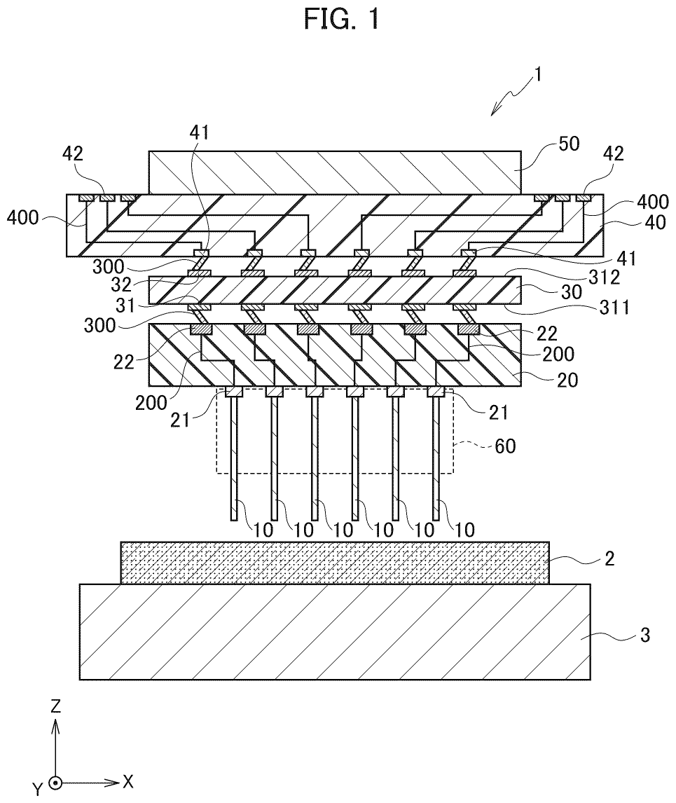

An electrical connection apparatus 1 according to a first embodiment shown in FIG. 1 is used for inspecting an object 2 to be inspected. The electrical connection apparatus 1 includes a plurality of probes 10 that come into contact with the object 2 to be inspected when the object is inspected, a wiring board 20 connected to the probes 10, a wiring sheet 30 laminated on the wiring board 20, and a printed board 40 laminated on the wiring sheet 30. The electrical connection apparatus 1 further includes a stiffener 50 laminated on the printed board 40. In the following description, a direction in which the electrical connection apparatus 1 is located when viewed from the object 2 to be inspected is defined as an upward direction, and a direction in which the object 2 to be inspected is located when viewed from the electrical connection apparatus 1 is defined as a downward direction. As shown in FIG. 1, a direction from the downward direction to the upward direction is defined as a Z direction, and a plane perpendicular to the Z direction is defined as an XY plane. In FIG. 1, a left-right direction of the drawing is defined as an X direction, and a front-back direction is defined as a Y direction. Further, a surface facing the upward direction of each component of the electrical connection apparatus 1 will be referred to as an upper surface, and a surface facing the downward direction will be referred to as a lower surface.

The probes 10 function as terminals for inspection for electrically connecting the object 2 to be inspected and an inspection device. The probes 10 have tips disposed so as to be in contact with the object 2 to be inspected and proximal ends connected to the tips. As shown in FIG. 1, the probes 10 may be supported by a probe head 60 through which the probes 10 pass. The probes 10 are held while passing through through-holes formed in the probe head 60, for example. The probe head 60 is fixed to the wiring board 20, for example. The proximal ends of the probes 10 are connected to the wiring board 20.

The object 2 to be inspected is mounted on a stage 3. The electrical connection apparatus 1 and the stage 3 are movable relative to one another in an up-down direction. When the object 2 to be inspected is inspected, a distance between the electrical connection apparatus 1 and the stage 3 is made small, and the tips of the probes 10 contact signal terminals (not shown) of the object 2 to be inspected. FIG. 1 shows a state in which the probes 10 and the object 2 to be inspected are separated.

The wiring board 20 includes first electrodes 21 electrically connected to the probes 10, internal wiring 200, and second electrodes 22. Each first electrode 21 is connected to a proximal end of any one of the plurality of probes 10 of the electrical connection apparatus 1. The second electrodes 22 are electrically connected to the first electrodes 21 via the internal wiring 200. A multilayer wiring board such as a Multi-Layer Organic (MLO) board or a Multi-Layer Ceramic (MLC) board may be used for the wiring board 20, for example.

The wiring sheet 30 includes a first sheet surface 311 which faces the wiring board 20, and a second sheet surface 312 which faces in an opposite direction of the first sheet surface 311 and faces the printed board 40. First connection portions 31 are arranged on the first sheet surface 311, and second connection portions 32 are arranged on the second sheet surface 312. Further, the wiring sheet 30 has an internal circuit (not shown in FIG. 1) electrically connected to at least any one of the first connection portions 31 and the second connection portions 32. The wiring sheet 30 has flexibility and elastically deforms in a thickness direction.

Each claw portion 300 with conductivity projecting obliquely relative to the first sheet surface 311 and the second sheet surface 312 perpendicular to the thickness direction of the wiring sheet 30 is arranged on at least any one of the first connection portion 31 and the second connection portion 32 of the wiring sheet 30.

The printed board 40 is arranged to face the wiring board 20 with the wiring sheet 30 therebetween. The printed board 40 includes first ends 41 arranged on a lower surface thereof facing the wiring sheet 30, second ends 42 arranged on an upper surface facing in an opposite direction of a first main surface, and wiring patterns 400 for electrically connecting the first ends 41 and the second ends 42. Each second end 42 of the wiring pattern 400 is electrically connected to an inspection device (not shown).

The first sheet surface 311 is a lower surface of the wiring sheet 30 facing the wiring board 20. The second sheet surface 312 is an upper surface of the wiring sheet 30 facing the printed board 40. In the wiring sheet 30 interposed between the wiring board 20 and the printed board 40, claw portions 300 are disposed on both the first connection portions 31 and the second connection portions 32. The first connection portions 31 of the wiring sheet 30 are connected to the second electrodes 22 of the wiring board 20 via the claw portions 300, and the second connection portions 32 are connected to the first ends 41 of the wiring patterns 400 of the printed board 40 via the claw portions 300. This electrically connects the internal wiring 200 of the wiring board 20 and the internal circuit of the wiring sheet 30, and electrically connects the wiring patterns 400 of the printed board 40 and the internal circuit of the wiring sheet 30.

As described above, the first connection portions 31 of the wiring sheet 30 are electrically connected to the second electrodes 22 of the wiring board 20, and the second connection portions 32 are electrically connected to the wiring patterns 400 of the printed board 40. In other words, the wiring sheet 30 has functions of an interposer between the wiring board 20 and the printed board 40.

The wiring board 20 may be a space transformer that transforms a distance between the proximal ends of the probes 10 to a distance between the first ends 41 of the printed board 40 when viewed from a direction normal to a main surface of the wiring board 20, for example. Due to the wiring board 20 being a space transformer, it is possible to electrically connect the proximal ends of the probes 10 arranged at a distance corresponding to a distance between signal terminals arranged on the object 2 to be inspected, to the wiring patterns 400 in the printed board 40 arranged at a distance larger than a distance between the proximal ends. Due to an increase in distance between the second ends 42 of the wiring patterns 400, the electrical connection between the wiring patterns 400 in the printed board 40 and the inspection device is facilitated.

As shown in FIG. 1, the stiffener 50 may be laminated on the printed board 40. The stiffener 50 has higher stiffness than the printed board 40, and ensures the mechanical strength of the electrical connection apparatus 1 by preventing the printed board 40 from being bent. In addition, the stiffener 50 may be used as a support for fixing each component of the electrical connection apparatus 1. The stiffener 50 may be fixed to the printed board 40 using screws, for example.

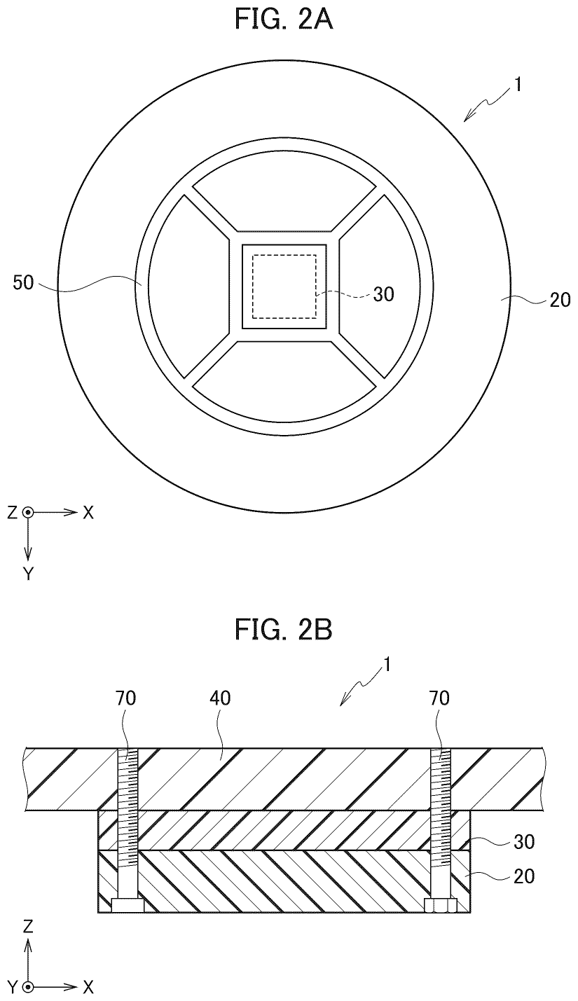

FIG. 2A is a plan view (hereinafter also referred to as “in plan view”) of a structure in which the wiring board 20, the wiring sheet 30, the printed board 40, and the stiffener 50 are laminated, as viewed from the Z direction. FIG. 2B is a cross-sectional view of a side surface as viewed from the Y direction of an XY plane perpendicular to the Z direction. FIG. 2B does not show the first electrodes 21 and the second electrodes 22 of the wiring board 20, the first connection portions 31 and the second connection portions 32 of the wiring sheet 30, and the wiring patterns 400 of the printed board 40.

The stiffener 50 is arranged on an upper surface of the printed board 40 that is circular in plan view. As shown in FIG. 2A, the stiffener 50 has a shape in which an outer circular ring and an inner rectangular ring are connected using spokes, for example. The wiring board 20 and the wiring sheet 30 are arranged in the vicinity of the center of a lower surface of the printed board 40. The wiring board 20, the wiring sheet 30, the printed board 40, and the stiffener 50 are fixed with screws, for example. FIG. 2B shows an example in which the wiring board 20, the wiring sheet 30, and the printed board 40 are joined using screws 70.

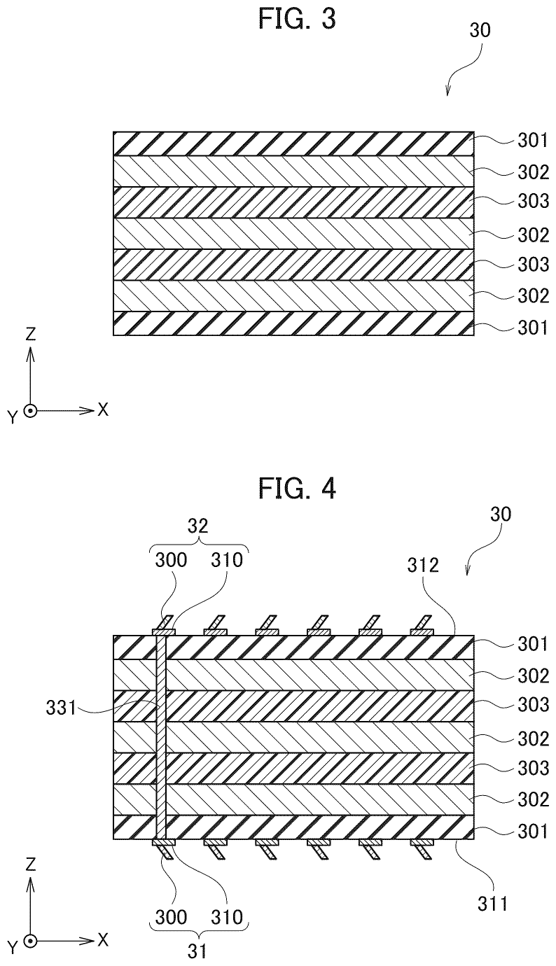

The wiring sheet 30 may have a structure in which a conductive film and an insulating film are laminated. An internal circuit may be constituted from a conductive pattern formed on a conductive film, for example. FIG. 3 shows an example of a configuration of the wiring sheet 30. FIG. 3 does not show the first connection portions 31 and the second connection portions 32.

The wiring sheet 30 shown in FIG. 3 has a structure in which a laminated body constituted by conductive films 302 and insulating films 303 is interposed between a pair of cover films 301 of insulating materials. The number of laminated bodies constituted by the conductive films 302 and the insulating films 303 can be set to any number. The conductive films 302 may be metal materials such as copper foils, for example. The insulating films 303 may be insulating materials such as polyimide sheets, for example. The cover films 301 may be insulating materials such as solder resists, for example. An adhesive may be used for joining the conductive films 302, the insulating films 303, and the cover films 301 to each other, for example. The wiring sheet 30 may have a structure in which a film (also referred to as a “base film”) of an insulating material is further interposed between laminated bodies including the conductive films 302 and the insulating films 303.

The wiring sheet 30 is flexible, and therefore irregularities on an upper surface of the wiring board 20 and irregularities on a lower surface of the printed board 40 are mitigated by the wiring sheet 30. Further, even if the outer shape of the wiring board 20 or the printed board 40 is distorted, the distortion is mitigated by the wiring sheet 30 and a structure of the electrical connection apparatus 1 is stabilized. This can suppress deterioration in the accuracy of the inspection of the object 2 to be inspected performed using the electrical connection apparatus 1.

Further, each claw portion 300 of the wiring sheet 30 is formed on a surface of each cover film 301 such that each claw portion 300 can be elastically deformed. That is, each claw portion 300 receives an external force generated by contact between the wiring sheet 30, and the wiring board 20 and the printed board 40, and approaches a surface of the wiring sheet 30. After removal of the external force, a state of each claw portion 300 returns to an original state. In this way, each claw portion 300 can be elastically deformed in the thickness direction of the wiring sheet 30.

When the wiring sheet 30 is interposed between the wiring board 20 and the printed board 40, the claw portions 300 is elastically deformed. This ensures the connection between the first connection portions 31 of the wiring sheet 30 and the second electrodes 22 of the wiring board 20. Even if the degrees of flatness of the first sheet surface 311 of the wiring sheet 30 and an upper surface of the wiring board 20 are different, the stability of the electrical connection between the internal circuit of the wiring sheet 30 and the internal wiring 200 of the wiring board 20 is maintained, for example. At the same time, the connection between the second connection portions 32 of the wiring sheet 30 and the first ends 41 of the wiring patterns 400 of the printed board 40 is ensured. Even if the degrees of flatness of the second sheet surface 312 of the wiring sheet 30 and a lower surface of the printed board 40 are different, the stability of the electrical connection between the internal circuit of the wiring sheet 30 and the wiring patterns 400 of the printed board 40 is maintained, for example.

Each claw portion 300 with conductivity which can be elastically deformed in the thickness direction of the wiring sheet 30 may be formed as follows, for example. First, a part of an insulating film on a surface of the wiring sheet 30 is lifted to form a projecting portion which projects obliquely from the surface. Thereafter, the projecting portion and a periphery thereof are plated with a conductive material. As a result, the projecting portion becomes each claw portion 300 with conductivity. As shown in FIG. 4, the periphery of each claw portion 300 becomes each support portion 310 for supporting each claw portion 300. Each claw portion 300 has a cantilever structure having a fixed end connected to each support portion 310, and a free end separated from the wiring sheet 30. Each support portion 310 with conductivity is electrically connected to the internal circuit of the wiring sheet 30. The internal circuit shown in FIG. 4 is short-circuit wiring 331 for electrically connecting the first connection portions 31 and the second connection portions 32. Each claw portion 300 and each support portion 310 may be formed by means of copper plating, for example.

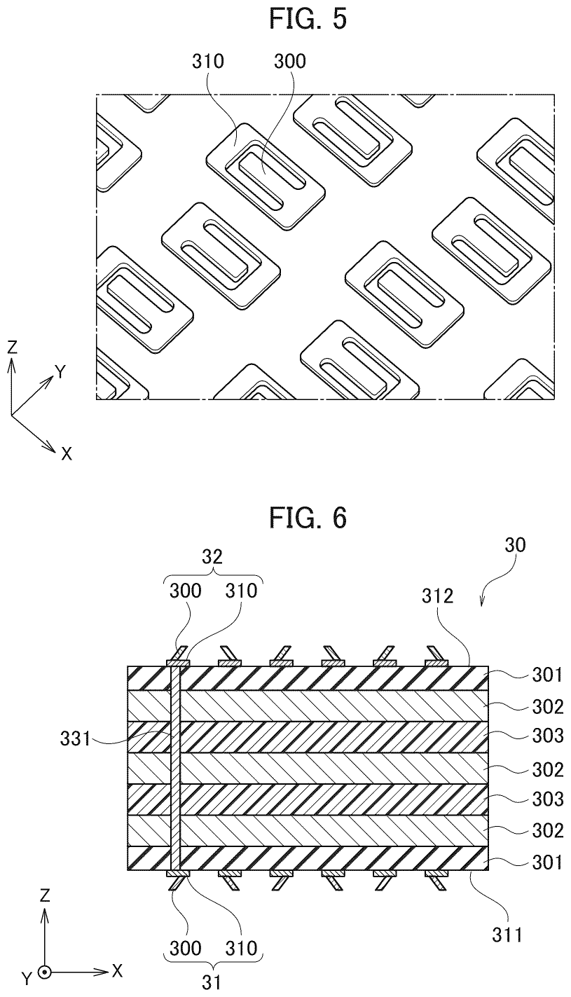

As shown in FIG. 5, the plurality of claw portions 300 may be arranged in a matrix in plan view viewed from a direction normal to the thickness direction (Z direction). Projecting directions of the claw portions 300 can be arbitrarily set. In the array of the claw portions 300 shown in FIG. 5, projecting directions of claw portions 300 arranged in the X direction are the same, for example. Meanwhile, projecting directions of adjacent claw portions 300 of claw portions 300 arranged in the Y direction are mutually opposite. FIG. 4 is a cross-sectional view of the claw portions in the X direction, for example. Alternatively, as shown in FIG. 6, projecting directions of adjacent claw portions 300 of a plurality of claw portions 300 arrayed in the same direction may be mutually opposite.

As shown in FIG. 6, by making the projecting directions of the claw portions 300 mutually opposite, a direction of a force applied to the wiring sheet 30 from the wiring board 20 and the printed board 40 is distributed, for example. This can suppress misalignment of the wiring board 20 or the printed board 40 relative to the wiring sheet 30 in the XY plane.

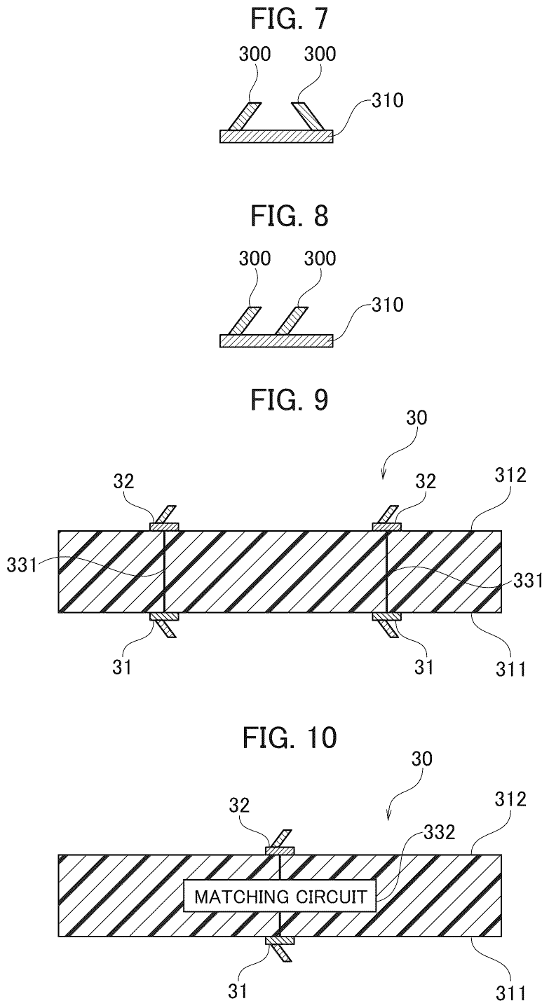

Although a case where one claw portion 300 is connected to one support portion 310 has been described as an example, the plurality of claw portions 300 may be connected to one support portion 310. As shown in FIG. 7, two claw portions 300 having different projecting directions may be connected to one support portion 310, for example. Alternatively, as shown in FIG. 8, two claw portions 300 having the same projecting direction may be connected to one support portion 310.

According to the configuration shown in FIG. 7, claw portions 300 contact the wiring board 20 and the printed board 40 from different directions. This can strengthen the electrical connection between the wiring sheet 30, and the wiring board 20 and the printed board 40. According to the configuration shown in FIG. 8, it is possible to decrease the length of the claw portions 300. When the claw portions 300 are short, high-frequency characteristics of the object 2 to be inspected can be measured favorably. However, the length of the claw portions 300 is set such that pressing forces by the claw portions 300 do not decrease by decreasing the length of the claw portions 300.

As described above, in the electrical connection apparatus 1 according to the first embodiment, the claw portions 300 with conductivity projecting obliquely are disposed on the first connection portions 31 and the second connection portions 32 of the wiring sheet 30. Therefore, according to the electrical connection apparatus 1 shown in FIG. 1, the electrical connection between the internal wiring 200 of the wiring board 20 and the wiring patterns 400 of the printed board 40 can be stabilized even if there is a difference in the degrees of flatness between the wiring board 20 and the printed board 40.

The wiring sheet 30 may be selected from among a plurality of wiring sheet candidates. Each of the wiring sheet candidates has first connection portions 31 arranged on the first sheet surface 311, second connection portions 32 arranged on the second sheet surface 312, and an internal circuit. Each of the wiring sheet candidates may include an internal circuit having a configuration different from that of another wiring sheet candidate. One wiring sheet 30 selected from among the plurality of wiring sheet candidates is laminated on the wiring board 20 such that the first connection portions 31 thereof are connected to the second electrodes 22 of the wiring board 20. The wiring sheet 30 may be configured in an attachable/detachable manner between the wiring board 20 and the printed board 40 in the electrical connection apparatus 1. In order to replace the wiring sheet 30 laminated on the wiring board 20 with another wiring sheet candidate, the wiring sheet 30 is attached and detached between the wiring board 20 and the printed board 40, for example.

An example of the configuration of wiring sheet candidates included in a wiring sheet group will be described below. In the following, when each of the wiring sheet candidates is not limited, the wiring sheet candidates will be collectively referred to as a wiring sheet 30.

An internal circuit of a wiring sheet 30 as any one of the group of wiring sheets may include a circuit for electrically connecting the first connection portions 31 and the second connection portions 32 (hereinafter also referred to as “interposer circuit”). When the interposer circuit is formed on the wiring sheet 30 of the structure shown in FIG. 3, wiring is formed, which passes through the cover films 301, the conductive films 302, and the insulating films 303, from the first sheet surface 311 to the second sheet surface 312 of the wiring sheet 30, for example.

If the internal circuit of the wiring sheet 30 includes the interposer circuit, the internal circuit of the wiring sheet 30 shown in FIG. 9 may include a circuit for short-circuiting the first connection portions 31 and the second connection portions 32. In the internal circuit of the wiring sheet 30 shown in FIG. 9, the first connection portions 31 and the second connection portions 32 are electrically short-circuited by the short-circuit wiring 331.

By attaching the wiring sheet 30 shown in FIG. 9 to the electrical connection apparatus 1, the probes 10 and the wiring patterns 400 in the printed board 40 are short-circuited via the internal circuit of the wiring sheet 30. This electrically connects the object 2 to be inspected and the inspection device. As a result, an electrical signal propagates between an inspection device such as an IC tester and the object 2 to be inspected, and characteristics of the object 2 to be inspected are measured. One first connection portion 31 and one second connection portion 32 are connected in a one-to-one relationship by means of the internal circuit of the wiring sheet 30, for example. Alternatively, one first connection portion 31 may be connected to a plurality of second connection portions 32, or a plurality of first connection portions 31 may be connected to one second connection portion 32 by means of the internal circuit.

When the internal circuit of the wiring sheet 30 includes the interposer circuit, the internal circuit may include a matching circuit 332 having a first terminal connected to each first connection portion 31 and a second terminal connected to each second connection portion 32, as shown in FIG. 10. The matching circuit 332 may perform impedance matching between each first connection portion 31 and each second connection portion 32. The matching circuit 332 may include a x-type filter, for example.

The internal circuit of the wiring sheet 30 may include a circuit for electrically connecting any one of the first connection portions 31 and another one of the first connection portions 31. In other words, the internal circuit of the wiring sheet 30 may include a circuit for electrically connecting an output terminal and an input terminal of the object 2 to be inspected (hereinafter also referred to as a “loopback circuit”). Two signal terminals of the object 2 to be inspected are electrically connected by the loopback circuit.

The internal circuit of the wiring sheet 30 may include a circuit for short-circuiting any one of the first connection portions 31 and another one of the first connection portions 31 as shown in FIG. 11, for example. In the internal circuit of the wiring sheet 30 shown in FIG. 11, the one first connection portion 31 and the other first connection portion 31 are electrically short-circuited by loopback wiring 333. By attaching the wiring sheet 30 shown in FIG. 11 to the electrical connection apparatus 1, one of the probes 10 and another one of the probes 10 are short-circuited via the internal circuit of the wiring sheet 30. This electrically connects one signal terminal and the other signal terminal of the object 2 to be inspected.

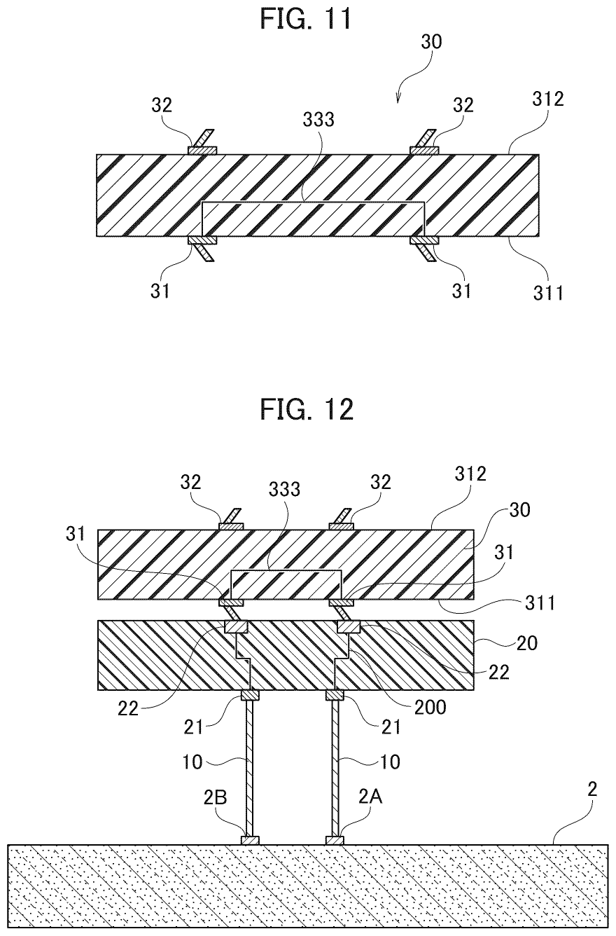

FIG. 12 shows a configuration in which a first signal terminal 2A of the object 2 to be inspected in contact with one of the probes 10, and a second signal terminal 2B of the object 2 to be inspected in contact with another one of the probes 10, are electrically connected via the loopback wiring 333 of the wiring sheet 30. Suppose that the object 2 to be inspected is a receiving circuit, the first signal terminal 2A is an output terminal of the object 2 to be inspected, and the second signal terminal 2B is an input terminal of the object 2 to be inspected, for example. In the above case, a transmission test can be performed by returning an output from the object 2 to be inspected to an input. In other words, it is possible to test whether an output portion and an input portion of the object 2 to be inspected are functioning normally, even if there is no destination equipment for transmission. As an inspection in accordance with a jitter tolerance test performed for the receiving circuit, an output signal output from the first signal terminal 2A (output terminal) may be input to the second signal terminal 2B (input terminal) as an input signal to inspect whether a specified error rate is ensured, for example.

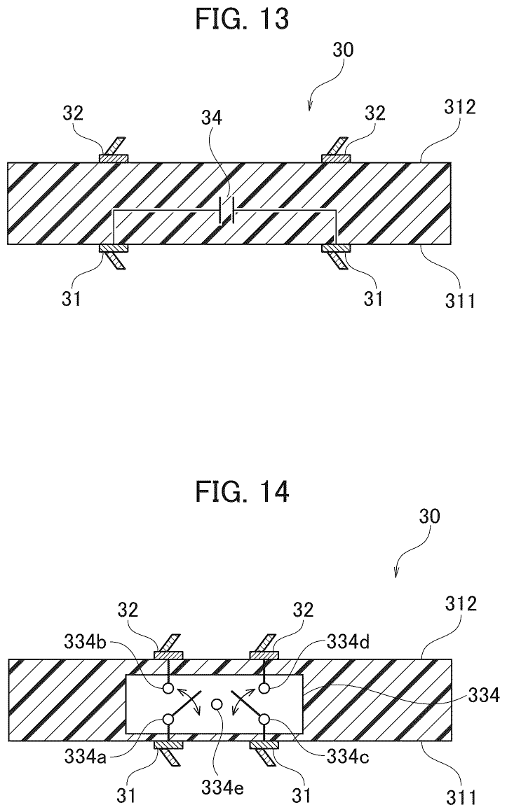

When the internal circuit of the wiring sheet 30 includes the loopback circuit, the internal circuit may include a circuit having a capacitor 34 connected in series between any one of the first connection portions 31 and another one of the first connection portions 31 as shown in FIG. 13. One terminal of the capacitor 34 is connected to the one first connection portion 31, and the other terminal of the capacitor 34 is connected to the other first connection portion 31. The capacitor 34 may be a capacitor formed using a semiconductor manufacturing process (hereinafter also referred to as a “process capacitor”).

Further, the internal circuit of the wiring sheet 30 may include a relay circuit that switches to electrically connect one of the first connection portions 31 to either one of the second connection portions 32 or another one of the first connection portions 31. The internal circuit shown in FIG. 14 includes a relay circuit 334 that constitutes either the interposer circuit for connecting a first connection portion 31 and a second connection portion 32, or the loopback circuit for connecting first connection portions 31 each other, for example.

When the relay circuit 334 shown in FIG. 14 constitutes the interposer circuit, a first contact terminal 334a and a second contact terminal 334b are connected, and a third contact terminal 334c and a fourth contact terminal 334d are connected. This electrically connects the first connection portion 31 and the second connection portion 32. When the relay circuit 334 constitutes the loopback circuit, the first contact terminal 334a and a common contact terminal 334e of the relay circuit 334 are connected, and the third contact terminal 334c and the common contact terminal 334e are connected. This electrically connects one of the first connection portions 31 and another one of the first connection portions 31.

Although examples of the internal circuit of the wiring sheet 30 have been described with reference to FIGS. 9 to 14, it is needless to say that the configuration of the internal circuit is not limited to the above. The internal circuit may include an inductor instead of the capacitor 34 shown in FIG. 13, or the internal circuit may include both a capacitor and an inductor, for example. In other words, the internal circuit of the wiring sheet 30 may include a passive circuit including any element. Further, the internal circuit may include a switching circuit using a diode or the like instead of the relay circuit 334 shown in FIG. 14.

An element included in the internal circuit of the wiring sheet 30 may be formed using a Micro Electro Mechanical Systems (MEMS) process, for example. By using the MEMS process, an element which is reduced in size can be formed integrally with the wiring sheet 30.

As described above, various circuit configurations as shown in FIGS. 9 to 14 can be implemented in the electrical connection apparatus 1 shown in FIG. 1 by merely replacing the wiring sheet 30 in the electrical connection apparatus 1, for example. Therefore, a plurality of types of measurements can be performed on the object 2 to be inspected using the electrical connection apparatus 1. A DC test may be performed on the object 2 to be inspected by mounting, in the electrical connection apparatus 1, the wiring sheet 30 including the internal circuit for short-circuiting the first connection portions 31 and the second connection portions 32, for example. Further, a high-frequency test may be performed on the object 2 to be inspected by mounting, in the electrical connection apparatus 1, the wiring sheet 30 including the internal circuit having the matching circuit or the loopback circuit.

Further, by arranging the relay circuit 334 in the wiring sheet 30 shown in FIG. 14 of the electrical connection apparatus 1, the wiring length of the interposer circuit and the loopback circuit can be reduced, compared to that when a relay element is arranged on the printed board 40. As a result, according to the electrical connection apparatus 1, it is possible to shorten a propagation path of an electrical signal and suppress the loss of an electrical signal and noise.

Further, by arranging the matching circuit 332 in the wiring sheet 30 shown in FIG. 10 of the electrical connection apparatus 1, wiring connected to the matching circuit 332 can be shortened. The matching circuit 332 can be arranged in the immediate vicinity of wiring for which impedance matching is to be performed, and therefore impedance matching can be performed effectively, for example.

In the measurement of the object 2 to be inspected, the stage 3 serves as a heat generation source. Therefore, an ambient temperature of a lower surface of the wiring board 20 facing the stage 3 is higher than that of another region. Therefore, by arranging the wiring sheet 30 on an upper surface of the wiring board 20, an increase in an ambient temperature of an electronic component constituting the internal circuit of the wiring sheet 30 can be suppressed compared to that of an electronic component arranged on the lower surface of the wiring board 20. As a result, the electronic component functions at an ambient temperature that is equal to or less than an allowable temperature, and the measurement of the object 2 to be inspected can be accurately performed.

As described above, the electrical connection apparatus 1 has the wiring sheet 30 including the internal circuit capable of constituting any circuit, which is interposed between the wiring board 20 and the printed board 40 in an attachable/detachable manner, and therefore it is possible to configure an arbitrary measurement system. As a result, characteristics of the object 2 to be inspected can be measured with high accuracy with the electrical connection apparatus 1.

### Second Embodiment

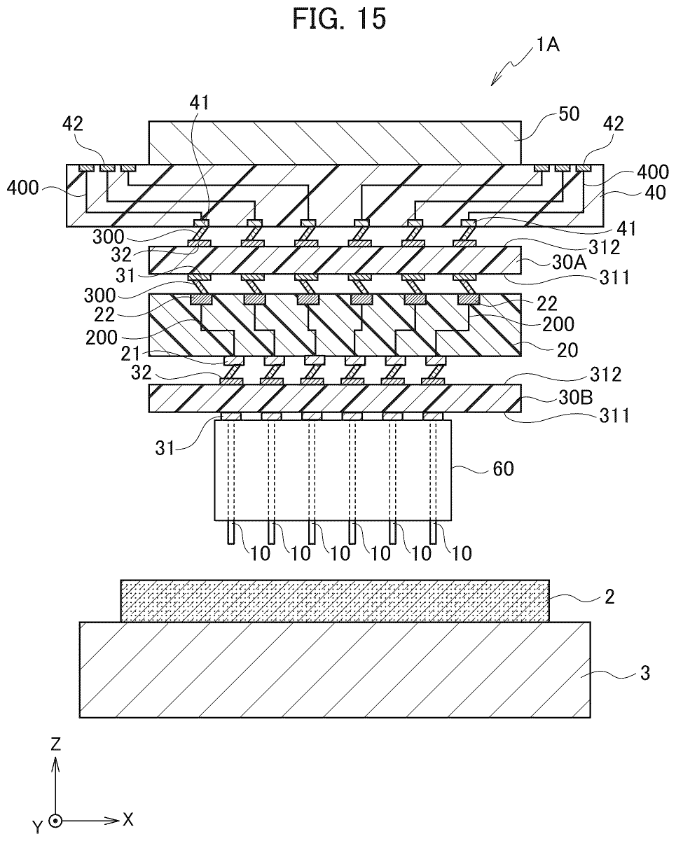

As shown in FIG. 15, an electrical connection apparatus 1A according to a second embodiment includes a first wiring sheet 30A interposed between the wiring board 20 and the printed board 40, and a second wiring sheet 30B interposed between the probe head 60 and the wiring board 20. In the following, when each of the first wiring sheet 30A and the second wiring sheet 30B is not limited, the wiring sheets will be collectively referred to as a wiring sheet 30. The electrical connection apparatus 1A shown in FIG. 15 differs from the electrical connection apparatus 1 according to the first embodiment in that the electrical connection apparatus 1A has the wiring sheet 30 interposed between the probe head 60 and the wiring board 20. Other configurations of the electrical connection apparatus 1A according to the second embodiment are the same as those of the electrical connection apparatus 1 of the first embodiment shown in FIG. 1.

The first connection portions 31 arranged on the first sheet surface 311 of the second wiring sheet 30B are in contact with proximal ends of the probes 10 exposed from the probe head 60, without interposing claw portions 300 therebetween. Meanwhile, the second connection portions 32 arranged on the second sheet surface 312 of the second wiring sheet 30B are connected to the first electrodes 21 of the wiring board 20 via the claw portions 300. That is, the claw portions 300 are arranged only on the second connection portions 32 of the second wiring sheet 30B, and the claw portions 300 are not arranged on the first connection portions 31. Other configurations of the second wiring sheet 30B are the same as those of the wiring sheet 30 described in the first embodiment.

Similar to the wiring sheet 30 of the electrical connection apparatus 1 shown in FIG. 1, both the first connection portions 31 and the second connection portions 32 of the first wiring sheet 30A have the claw portions 300. The first connection portions 31 of the first wiring sheet 30A are connected to the second electrodes 22 of the wiring board 20 via the claw portions 300. The second connection portions 32 are connected to the wiring patterns 400 in the printed board 40 via the claw portions 300.

The electrical connection apparatus 1A is configured such that the wiring sheet 30 with flexibility is interposed between the proximal ends of the probes 10 and the wiring board 20. According to the electrical connection apparatus 1A, the contact between the probes 10 and the object 2 to be inspected is stabilized by means of a preload function which is obtained by the wiring sheet 30, and which is for generating a pressing force between the wiring sheet 30 and the probes 10. As a result, the accuracy of the measurement of the object 2 to be inspected can be enhanced.

Electronic components can be mounted on both the first wiring sheet 30A and the second wiring sheet 30B in the electrical connection apparatus 1A. This can increase the number of electronic components mounted in the electrical connection apparatus 1A. Further, it is possible to arrange an electronic component near the object 2 to be inspected by mounting the electronic component on the second wiring sheet 30B in the electrical connection apparatus 1A. This can reduce the wiring length between the object 2 to be inspected and the electronic component. As a result, it is possible to enhance the accuracy of measurement performed on the object 2 to be inspected.

Further, the second wiring sheet 30B with flexibility which is interposed between the probe head 60 and the wiring board 20 in the electrical connection apparatus 1A can mitigate warpages and irregularities of surfaces of the probe head 60 and the wiring board 20. This can suppress rattling and contact failure of the electrical connection apparatus 1A caused by a gap between the probe head 60 and the wiring board 20.

Other configurations of the electrical connection apparatus 1A according to the second embodiment are substantially the same as those of the electrical connection apparatus of the first embodiment, and duplicated description thereof will be omitted. The wiring sheet 30 including the internal circuit capable of constituting any circuit described with reference to FIGS. 9 to 14 can be interposed between the probe head 60 and the wiring board 20 in an attachable/detachable manner, for example.

### Third Embodiment

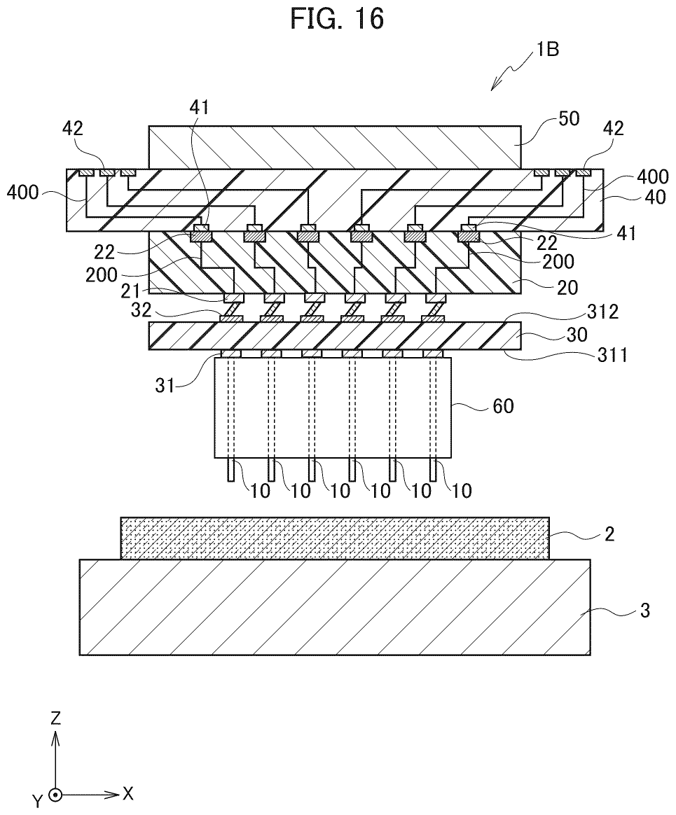

As shown in FIG. 16, in an electrical connection apparatus 1B according to a third embodiment, the wiring sheet 30 is interposed between the probe head 60 and the wiring board 20 instead of the wiring sheet 30 being interposed between the wiring board 20 and the printed board 40. Other configurations of the electrical connection apparatus 1B according to the third embodiment are the same as those of the electrical connection apparatus of the second embodiment shown in FIG. 15.

The first connection portions 31 arranged on the first sheet surface 311 of the wiring sheet 30 in the electrical connection apparatus 1B shown in FIG. 16 are in contact with proximal ends of the probes 10 without interposing claw portions 300 therebetween. Meanwhile, the second connection portions 32 arranged on the second sheet surface 312 of the wiring sheet 30 are connected to the first electrodes 21 of the wiring board 20 via the claw portion 300. That is, as shown in FIG. 16, the claw portions 300 are arranged only on the second connection portions 32 of the wiring sheet 30, and the claw portions 300 are not arranged on the first connection portions 31.

According to the electrical connection apparatus 1B having the wiring sheet 30 with flexibility which is interposed between the proximal ends of the probes 10 and the wiring board 20, the contact between the probes 10 and the object 2 to be inspected is stabilized by means of a preload function which is obtained by the wiring sheet 30. As a result, the accuracy of the measurement of the object 2 to be inspected can be enhanced.

Further, the wiring sheet 30 with flexibility which is interposed between the probe head 60 and the wiring board 20 in the electrical connection apparatus 1B can mitigate warpages and irregularities of surfaces of the probe head 60 and the wiring board 20. This can suppress the rattling and contact failure of the electrical connection apparatus 1B caused by a gap between the probe head 60 and the wiring board 20.

Other configurations of the electrical connection apparatus 1B according to the third embodiment are substantially the same as those of the electrical connection apparatuses of the first and second embodiments, and duplicated descriptions thereof will be omitted. The wiring sheet 30 including the internal circuit capable of constituting any circuit described with reference to FIGS. 9 to 14 can be interposed between the probe head 60 and the wiring board 20 in an attachable/detachable manner, for example.

### Other Embodiments

Although embodiments of the present invention have been described above, the discussion and drawings forming part of this disclosure should not be construed as limiting the invention. Various alternative embodiments, examples, and operational techniques will be apparent to those skilled in the art from this disclosure.

The wiring sheet 30 may include an internal circuit in which a plurality of types of circuit configurations are mixed, for example. The wiring sheet 30 may include an internal circuit in which the short-circuit wiring 331 and the matching circuit 332 are mixed, for example. Alternatively, the wiring sheet 30 may include an internal circuit in which an interposer circuit and a loopback circuit are mixed. The internal circuit may include the short-circuit wiring 331, the matching circuit 332, and the loopback wiring 333, or may further include the relay circuit 334, for example. Further, the loopback circuit may include the matching circuit 332. In this way, any circuit can be configured in the internal circuit of the wiring sheet 30.

As described above, by mounting, in the electrical connection apparatus 1, the wiring sheet 30 including the internal circuit in which any circuit configurations are mixed, a plurality of types of measurements can be performed on the object 2 to be inspected with one wiring sheet 30.

In the case described above, terminals for inspection that contact signal terminals of the object 2 to be inspected are the probes 10. When the terminals for inspection are the probes 10, it is possible to measure electrical characteristics of an object 2 to be inspected not separated from a wafer or an object 2 to be inspected which is converted into a chip. Meanwhile, the wiring sheet 30 may be mounted in an electrical connection apparatus including a test socket, to support the measurement of electrical characteristics of the object 2 to be inspected performed in a state where the object 2 to be inspected is mounted in a package or the like. The test socket may be arranged on the wiring board 20, the test socket having a terminal for inspection connected to an external terminal of the package in which the object 2 to be inspected is mounted, instead of the probes 10 in the electrical connection apparatus 1 shown in FIG. 1, for example.

In this way, it is needless to say that the present invention includes various embodiments not described above. Therefore, the technical scope of the present invention is defined only by matters specified in the invention that are within the scope of claims appropriate from the above description.

### REFERENCE SIGNS LIST

1, 1A, 1B Electrical connection apparatus
10 Probe
20 Wiring board
21 First electrode
22 Second electrode
30 Wiring sheet
30A First wiring sheet
30B Second wiring sheet
31 First connection portion
32 Second connection portion
40 Printed board
41 First end
42 Second end
50 Stiffener
60 Probe head
200 Internal wiring
300 Claw portion
301 Cover film
302 Conductive film
303 Insulating film
310 Support portion
311 First sheet surface
312 Second sheet surface
400 Wiring pattern

What is claimed is:

1. An electrical connection apparatus used for inspecting an object to be inspected, the electrical connection apparatus comprising:
a terminal for inspection having a tip disposed so as to be in contact with the object to be inspected and a proximal end connected to the tip;
a wiring board including a first electrode electrically connected to the terminal for inspection, internal wiring, and a second electrode electrically connected to the first electrode via the internal wiring; and
a wiring sheet with flexibility including a first connection portion arranged on a first sheet surface, a second connection portion arranged on a second sheet surface which faces in an opposite direction of the first sheet surface, and an internal circuit electrically connected to at least any one of the first connection portion and the second connection portion, wherein
a claw portion with conductivity projecting obliquely relative to a surface perpendicular to a thickness direction of the wiring sheet is arranged on at least any one of the first connection portion and the second connection portion, and
the internal wiring of the wiring board and the internal circuit of the wiring sheet are electrically connected via the claw portion.

2. The electrical connection apparatus according to claim 1, further comprising:
a printed board including a wiring pattern, wherein
the wiring sheet is interposed between the wiring board and the printed board,
the claw portion is arranged on the first connection portion and the second connection portion,
the first connection portion is connected to the second electrode via the claw portion, and
the second connection portion is connected to the wiring pattern via the claw portion.

3. The electrical connection apparatus according to claim 1, further comprising:
a probe head for holding the terminal for inspection, wherein
the wiring sheet is interposed between the probe head and the wiring board,
the claw portion is arranged only on the second connection portion,
the second connection portion is connected to the first electrode via the claw portion, and
the first connection portion is connected to the proximal end of the terminal for inspection exposed from the probe head without interposing the claw portion therebetween.

4. The electrical connection apparatus according to claim 1, wherein
the claw portion can be elastically deformed in the thickness direction.

5. The electrical connection apparatus according to claim 4, wherein
at least any one of the first connection portion and the second connection portion includes a support portion fixed to the wiring sheet, and
the claw portion has a cantilever structure having a fixed end connected to the support portion and a free end separated from the wiring sheet.

6. The electrical connection apparatus according to claim 5, wherein
the claw portion is provided in plurality, and two of the claw portions having the same projecting direction are connected to the support portion.

7. The electrical connection apparatus according to claim 5, wherein
the claw portion is provided in plurality, and two of the claw portions having different projecting directions are connected to the support portion.

8. The electrical connection apparatus according to claim 1, wherein
the claw portion is provided in plurality, and the claw portions are arranged in a matrix in plan view viewed from a direction normal to the thickness direction.

9. The electrical connection apparatus according to claim 8, wherein
the claw portions having mutually opposite projecting directions are adjacent to each other.

10. The electrical connection apparatus according to claim 1, wherein
the wiring sheet has a structure in which a laminated body constituted by a conductive film and an insulating film is interposed between cover films of an insulating material.

11. The electrical connection apparatus according to claim 1, wherein
the proximal end is provided in plurality, and the wiring board is a space transformer that transforms a distance between the proximal ends of the terminal for inspection when viewed from a direction normal to a main surface of the wiring board.

12. The electrical connection apparatus according to claim 1, wherein
the terminal for inspection is a probe having a proximal end connected to the first electrode of the wiring board and a tip in contact with a signal terminal of the object to be inspected.

13. The electrical connection apparatus according to claim 1, wherein
the terminal for inspection is arranged in a test socket connected to an external terminal of a package in which the object to be inspected is mounted.
